(19) United States
(12) Patent Application Publication
(10) Pub. No.: US 2010/0022066 A1
(43) Pub. Date: Jan. 28, 2010

(54) METHOD FOR PRODUCING HIGH-RESISTANCE SIMOX WAFER

(75) Inventors: Yoshiro Aoki, Tokyo (JP); Naoshi Adachi, Tokyo (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SUMCO CORPORATION, Tokyo (JP)

(21) Appl. No.: 12/504,577

(22) Filed: Jul. 16, 2009

(30) Foreign Application Priority Data
Jul. 23, 2008 (JP) 2008-189647

(51) Int. Cl. H01L 21/762

(52) U.S. Cl. 438/423; 257/E21.563

(57) ABSTRACT

A method for producing a high-resistance SIMOX wafer wherein oxygen diffused inside of a wafer by the heat treatment at a high temperature in an oxidizing atmosphere can be reduced to suppress the occurrence of thermal donor. In one embodiment, a heating-rapid cooling treatment is conducted after the heat treatment at a high temperature in an oxidizing atmosphere to implant vacancies from a surface of a wafer into an interior thereof to thereby easily precipitate oxygen diffused inside the wafer during the heat treatment.

### BACKGROUND OF THE INVENTION

1. Field of the Invention

This invention relates to a method for producing an SIMOX (Separation by Implanted Oxygen) wafer, and more particularly to a method for producing a high-resistance SIMOX wafer wherein oxygen diffused inside of the wafer by a heat treatment at a high temperature in an oxidizing atmosphere for forming an SOI (Silicon on Insulator) layer is reduced to suppress an occurrence of thermal donor.

2. Description of the Related Art

As one of production methods for SOI wafer, there is a SIMOX method (see Non-patent Document 1). Although there are some processes in the SIMOX method, the current SIMOX technique is based on a low-dose SIMOX technique (see Non-patent Document 2).

In the low-dose SIMOX wafer, since a thickness of BOX (Buried Oxide) layer is thin, the reliability of BOX comes into problem. In order to improve it, there have been developed ITOX (Internal Thermal Oxidation) technique (see Non-patent Document 3 and Patent Document 1) and MLD (Modified Low Dose) SIMOX (see Patent Document 2).

Even in each of the above SIMOX methods, a heat treatment at a high temperature of not lower than 1300° C. in an oxidizing atmosphere is required for forming a high-quality BOX layer through the SIMOX method, and oxygen diffused toward an interior of the wafer during the heat treatment remains in the wafer even after the heat treatment. Therefore, there is a problem that when a heat treatment of about 400-500° C. is conducted at a device production step, thermal donor is formed, and particularly the resistivity lowers in an SIMOX wafer using a high-resistance wafer.

With respect to this problem, Patent Document 3 proposes a method wherein a temperature of not higher than 1250° C. but not lower than 800° C. is kept for a given time in a final stage of the high-temperature heat treatment.
[Non-patent Document 1] K. Izumi et al.: Electron. Lett. 14 (1978) 593
[Non-patent Document 2] S. Nakashima et al.: J. Mater. Res. 8(1993) 523
[Non-patent Document 3] S. Nakashima et al. Proc. 1994 IEEE International SOI Conference (1994) 71
[Patent Document 1] JP-A-H07-263538
[Patent Document 2] U.S. Pat. No. 5,930,643
[Patent Document 3] JP-A-2002-289820

In the aforementioned methods, however, oxygen diffused inside cannot be diffused outward sufficiently, so that the oxygen concentration cannot be reduced other than the vicinity of the wafer surface. As a result, when a heat treatment of about 400 to 500° C. is conducted, a high resistance can be maintained in the vicinity of the wafer surface, but thermal donor is formed in a portion of a few μm inward from the wafer surface to lower the resistivity.

As a method for reducing the oxygen concentration is also considered a method wherein two-stage heat treatment of low and high temperatures is conducted to precipitate oxygen after the heat treatment at a high temperature in an oxidizing atmosphere. However, the profile of oxygen concentration in the wafer after the heat treatment at a high temperature in an oxidizing atmosphere shows a minimum value at the wafer surface and a maximum value at a position of approximately 100 μm from the wafer surface, and also interstitial silicon is implanted from the wafer surface in association with the oxidization, so that it is difficult to precipitate oxygen in a depth region of several tens μm from the wafer surface.

### SUMMARY OF THE INVENTION

Considering the above problems, it is an object of the invention to provide a method for producing a high-resistance SIMOX wafer wherein oxygen diffused inside of a wafer by the heat treatment at a high temperature in an oxidizing atmosphere can be reduced to suppress the occurrence of thermal donor.

Moreover, the thermal donor means that oxygen and vacancies are changed into donors by the heat treatment at about 450° C., and if the thermal donor is generated, the resistivity particularly lowers from a desired value in a high-resistance wafer.

In order to achieve the above object, the inventors have made various studies about a method for reducing oxygen diffused toward the interior of the wafer due to the heat treatment at a high temperature in an oxidizing atmosphere. As a result, there has been reached a method wherein a heating-rapid cooling treatment (RTA (Rapid Thermal Annealing) treatment is a typical example) is conducted after the heat treatment at a high temperature in an oxidizing atmosphere to implant vacancies from a surface of a wafer into an interior thereof to thereby easily precipitate oxygen diffused inside of the wafer during the heat treatment.

That is, the summary of the invention is as follows.

(1) A method for producing a high-resistance SIMOX wafer comprising implanting oxygen ions into a high-resistance silicon wafer and then conducting a heat treatment at a high temperature in an oxidizing atmosphere;

removing an oxide film from the surface of the silicon wafer after the heat treatment; and

conducting a heating-rapid cooling treatment to implant vacancies into the silicon wafer.

(2) A method for producing a high-resistance SIMOX wafer according to the item (1), wherein the silicon wafer has a resistivity of not less than 100 Ωcm.

(3) A method for producing a high resistance SIMOX wafer according to the item (1) or (2), wherein the heating-rapid cooling treatment is conducted by heating to a temperature region of not lower than 1100° C. and thereafter cooling at a rate of not less than 33° C./sec.

(4) A method for producing a high resistance SIMOX wafer according to any one of the items (1)-(3), wherein an oxygen precipitation treatment is conducted followed by the heating-rapid cooling treatment.

According to the invention, it is possible to provide a high-resistance SIMOX wafer in which a high-resistance silicon wafer is used and subjected to a heat treatment at a high temperature in an oxidizing atmosphere and then a heating-rapid cooling treatment, whereby oxygen diffused inside of the wafer due to the heat treatment at the high temperature in the oxidizing atmosphere can be precipitated through vacancies implanted by the heating-rapid cooling treatment to reduce oxygen inside the wafer to thereby suppress the occurrence of thermal donor.

### BRIEF DESCRIPTION OF THE DRAWING

The invention will be described with reference to the accompanying drawing, wherein:

FIG. 1 is a flow chart showing production steps of a SIMOX wafer according to the invention.

### DESCRIPTION OF THE PREFERRED EMBODIMENTS

An embodiment of the invention will be described below.

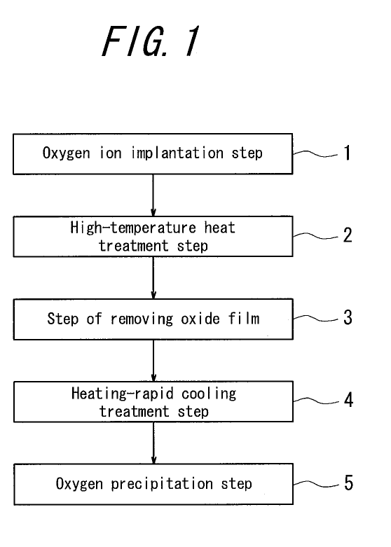

FIG. 1 is a flow chart showing production steps of an embodiment of the high-resistance SIMOX wafer according to the invention. As shown in FIG. 1, the production method according to the invention comprises a step 1 of implanting oxygen ions into a silicon wafer, a step 2 of conducting a heat treatment at a high temperature in an oxidizing atmosphere, a step 3 of removing an oxide film, and a step 4 of conducting a heating-rapid cooling treatment. Further, the production method according to the invention is preferable to comprise a step 5 of precipitating oxygen.

Although the method for producing a high-resistance SIMOX wafer according to the invention will be described below by applying to MLD-SIMOX method, the invention is not limited thereto, and may be applied to other SIMOX methods such as ITOX-SIMOX method and the like.

In the MLD-SIMOX method, the oxygen ion implantation is conducted at two stages in the oxygen ion implantation step 1. The first oxygen ion implantation is conducted by heating a silicon wafer, and subsequently the second oxygen ion implantation is conducted by lowering the temperature of the silicon wafer to about room temperature. That is, in the first oxygen ion implantation is formed a high oxygen concentration layer while maintaining the surface of the silicon wafer at a state of a single crystal by heating the silicon wafer, and in the second ion implantation is formed an amorphous layer.

In the subsequent high-temperature heat treatment step 2, a BOX layer is formed by conducting a heat treatment in a mixed atmosphere of oxygen and an inert gas at a heat treating temperature of not lower than 1300° C., more preferably 1320 to 1350° C. for 6 to 12 hours. By adjusting an oxygen partial pressure and a heat treating time in the oxidation treatment is adjusted a thickness of a surface oxide film to control a thickness of an SOI layer. As the inert gas to be mixed with oxygen may be used nitrogen or argon.

The oxygen concentration of the atmosphere is preferable to be 10% to 100%. When the oxygen concentration is less than 10%, it is feared that the effect of improving the quality of the BOX layer is not sufficient.

Since an oxide film is formed on the surface of the silicon wafer in the heat treatment step 2, such an oxide film is removed in the step 3 of removing the oxide film. In this regard, the oxide film may be completely removed, or a native oxide film, i.e., an oxide film having a thickness of not more than 1 nm may remain.

Thereafter, vacancies are implanted from the wafer surface through the step 4 of conducting the heating-rapid cooling treatment (RTA). In order to implant vacancies from the wafer surface efficiently, the RTA treatment is preferable to be conducted in a nitrogen-containing atmosphere. Because, when the RTA treatment is conducted under a nitrogen atmosphere, oxygen is easily precipitated in a depth region several tens μm from the wafer surface by residual vacancies generated at the high temperature, and vacancies diffused inward from the wafer surface through a nitride film formed on the wafer surface.

Also, the RTA treatment can be conducted in an argon-containing atmosphere. In case of the RTA treatment under an argon atmosphere, oxygen is easily precipitated inside the wafer through residual vacancies generated at the high temperature. The heat treating temperature is preferably 1100 to 1350° C. When the heat treating temperature is lower than 1100° C., sufficient implantation of vacancies is not attained, while when it exceeds 1350° C., the occurrence of slip dislocation is feared. On the other hand, as the cooling rate from the highest temperature becomes slow, the outward diffusion of vacancies is promoted to lower the vacancy concentration in the vicinity of the wafer surface, so that the cooling rate is preferable to be not less than 33° C./sec. The upper limit of the cooling rate depends on an apparatus, and it is preferable that the cooling rate is faster.

In the method for producing a high-resistance SIMOX wafer according to the invention, the concentration peak position of vacancies implanted from the wafer surface through the RTA treatment is preferable to be closer to a wafer surface side than a concentration peak position of oxygen after the heat treatment at the high temperature in the oxidizing atmosphere. If the concentration peak position of vacancies is closer to the inside of the wafer than the concentration peak position of oxygen, it becomes difficult to precipitate oxygen in a surface layer of the wafer due to an interstitial silicon atom generated and diffused in association with oxygen precipitation inside of the wafer.

After the vacancies are implanted by the RTA treatment, if oxygen precipitation is possible in a device production step, the treatment for oxygen precipitation is not needed, but if the oxygen precipitation is difficult in the device production step, it is preferable to further add the oxygen precipitation step 5.

The oxygen precipitation treatment is a common treatment comprising a treatment for the formation of oxygen precipitation nuclei at 700 to 900° C. for 4 hours and a treatment for the growth of oxygen precipitates at 1000° C. for 16 hours.

### EXAMPLES

A high-resistance SIMOX wafer prepared by the production method shown in FIG. 1 is subjected to a heat treatment at 450° C. for 1 hour, and then a resistivity thereof is measured by an SR (Spreading Resistance) method. The SR method is a method wherein the wafer is polished in an oblique direction and its resistivity value is measured in a depth direction.

In SIMOX wafers of Examples 1 to 6, a high-resistance silicon wafer shown in Table 1 is subjected to an RTA treatment under conditions shown in Table 1 after the oxygen ion implantation and high-temperature heat treatment steps.

On the other hand, the RTA treatment is not conducted in SIMOX wafer of Comparative Example 1. The measuring conditions and results are shown in Table 1.

TABLE 1

| | | RTA treatment | | |
|---|---|---|---|---|
| | Resistivity | Highest | | |
| | of silicon | temperature | Cooling rate | Measured value |
| | wafer [Ωcm] | [° C.] | [° C./sec] | (resistivity) |
| Example 1 | 100 | 1100 | 33 | 100 |
| Example 2 | 100 | 1200 | 33 | 100 |
| Example 3 | 100 | 1350 | 33 | 100 |
| Example 4 | 100 | 1000 | 33 | 70 |
| Example 5 | 100 | 1200 | 10 | 70 |
| Example 6 | 70 | 1200 | 33 | 70 |

| | | | |
|---|---|---|---|
| Comparative | 100 | None | 40 |
| Example 1 | | | |

As seen from Table 1, the change of resistivity is small in SIMOX wafers of Examples.

As described above, according to the invention, it is possible to provide a high-resistance SIMOX wafer in which a high-resistance silicon wafer is used and subjected to a heat treatment at a high temperature in an oxidizing atmosphere and then a heating-rapid cooling treatment, whereby oxygen diffused inside of the wafer due to the heat treatment at the high temperature in the oxidizing atmosphere can be precipitated through vacancies implanted by the heating-rapid cooling treatment to reduce oxygen inside the wafer to thereby suppress the occurrence of thermal donor.

1. A method for producing a high-resistance SIMOX wafer comprising:
implanting oxygen ions into a high-resistance silicon wafer and then conducting a heat treatment at a high temperature in an oxidizing atmosphere;
removing an oxide film from the surface of the silicon wafer after the heat treatment; and
conducting a heating-rapid cooling treatment to implant vacancies into the silicon wafer.

2. The method for producing a high-resistance SIMOX wafer according to claim 1, wherein the silicon wafer has a resistivity of not less than 100 Ωcm.

3. The method for producing a high resistance SIMOX wafer according to claim 1, wherein the heating-rapid cooling treatment is conducted by heating to a temperature region of not lower than 1100° C. and thereafter cooling at a rate of not less than 33° C./sec.

4. The method for producing a high resistance SIMOX wafer according to claim 1, wherein an oxygen precipitation treatment is conducted followed by the heating-rapid cooling treatment.
